(19) United States
(12) Patent Application Publication
(10) Pub. No.: US 2023/0227959 A1
(43) Pub. Date: Jul. 20, 2023

(54) METHOD FOR MANUFACTURING PATTERNED SURFACE COATING AND AUTOMOBILE HEAT DISSIPATION DEVICE HAVING PATTERNED SURFACE COATING

(71) Applicant: AMULAIRE THERMAL TECHNOLOGY, INC., New Taipei City (TW)

(72) Inventors: Yi-Hsin HUANG, New Taipei City (TW); Ching-Ming YANG, New Taipei City (TW); Tze-Yang YEH, New Taipei City (TW)

(21) Appl. No.: 17/577,228

(22) Filed: Jan. 17, 2022

(51) Int. Cl. C23C 14/04; C23C 14/16; C23C 14/34; C23C 14/54; H01L 23/373

(52) U.S. Cl. CPC C23C 14/042; C23C 14/16; C23C 14/34; C23C 14/542; H01L 23/3736

(57) ABSTRACT

A method for manufacturing a patterned surface coating of an automobile heat dissipation device and an automobile heat dissipation device having a patterned surface coating are provided. The method for manufacturing the patterned surface coating of the automobile heat dissipation device includes providing a metal heat dissipation device, and forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device.

### FIELD OF THE DISCLOSURE

The present disclosure relates to an automobile heat dissipation device, and more particularly to a method for manufacturing a patterned surface coating of an automobile heat dissipation device and an automobile heat dissipation device having a patterned surface coating.

### BACKGROUND OF THE DISCLOSURE

Overheating of conventional automobile electronic modules, such as insulated gate bipolar transistor (IGBT) modules and advanced driver-assistance system (ADAS) modules, may result in deterioration of performance and damage thereof.

Metal heat dissipation devices are usually used for the conventional automobile electronic modules. However, with the rapid development of modern industry, there are higher demands on the functionality of the metal heat dissipation devices, such as a corrosion resistant ability or a bonding strength thereof, which cannot be met by conventional metal heat dissipation devices.

### SUMMARY OF THE DISCLOSURE

In response to the above-referenced technical inadequacies, the present disclosure provides a method for manufacturing a patterned surface coating of an automobile heat dissipation device and an automobile heat dissipation device having a patterned surface coating.

In one aspect, the present disclosure provides a method for manufacturing a patterned surface coating of an automobile heat dissipation device, and the method includes (a) providing a metal heat dissipation device; and (b) forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device.

In certain embodiments, in step (b), at least one masking area is formed on a surface of the metal heat dissipation device by a masking process, so that the sputtered metal layer is not formed in the at least one masking area, and the sputtered metal layer that is patterned is formed on the surface of the metal heat dissipation device.

In certain embodiments, the sputtered metal layer is formed at a vacuum level of less than 10⁻² mbar.

In certain embodiments, the sputtered metal layer is formed at a sputtering power of 1000 W or more.

In certain embodiments, a fin structure is disposed in the metal heat dissipation device.

In certain embodiments, the metal heat dissipation device is a water-cooled metal heat dissipation device or an air-cooled metal heat dissipation device.

In certain embodiments, the metal heat dissipation device is a closed metal heat dissipation device or a semi-open metal heat dissipation device.

In certain embodiments, the metal heat dissipation device is made of at least one of aluminum, aluminum alloy, copper, and copper alloy.

In certain embodiments, the sputtered metal layer is made of nickel, nickel alloy, copper, copper alloy, silver, or silver alloy.

In another aspect, the present disclosure provides an automobile heat dissipation device having a patterned surface coating, which includes a metal heat dissipation device and a sputtered metal layer. The sputtered metal layer is partially formed on an upper surface of the metal heat dissipation device by sputtering so that the sputtered metal layer is patterned. A thickness of the sputtered metal layer is between 1 μm and 3 μm, and the sputtered metal layer covers an area less than 90% of an area of the upper surface of the metal heat dissipation device.

Therefore, in the method for manufacturing the patterned surface coating of the automobile heat dissipation device and the automobile heat dissipation device having the patterned surface coating provided by the present disclosure, by virtue of “providing the metal heat dissipation device” and “forming the sputtered metal layer that is patterned on the upper surface of the metal heat dissipation device by sputtering, allowing the thickness of the metal sputtered layer to be between 1 μm and 3 μm, and allowing the sputtered metal layer to cover the area less than 90% of the area of the upper surface of the metal heat dissipation device,” a functional area that is patterned is formed on the upper surface of the metal heat dissipation device, so as to effectively enhance a soldering functionality, a corrosion resistant property, or a sintering ability of the metal heat dissipation device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a metal heat dissipation device according to one embodiment of the present disclosure; and

FIG. 2 is a schematic side view of the metal heat dissipation device having a sputtered metal layer that is pattered and formed on an upper surface thereof according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Embodiments

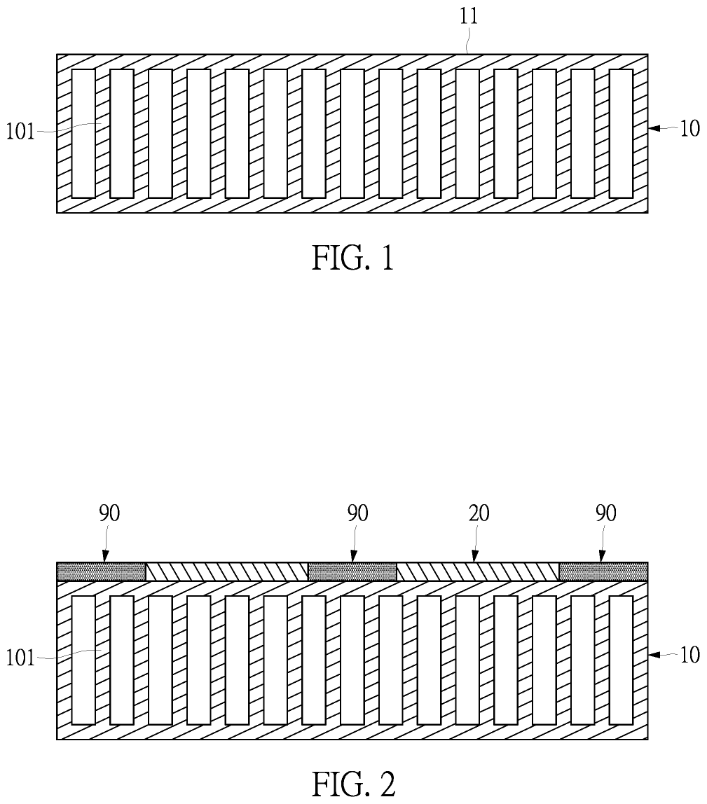

Referring to FIG. 1 and FIG. 2, embodiments of the present disclosure provide a method for manufacturing a patterned surface coating of an automobile heat dissipation device, and the method includes the following steps.

In step (a), a metal heat dissipation device 10 is provided. Further, in the present embodiment, a fin structure 101 is disposed in the metal heat dissipation device 10, and the fin structure 101 can be a plate fin or a pin fin, but is not limited thereto. Furthermore, the metal heat dissipation device 10 can be a water-cooled metal heat dissipation device or an air-cooled metal heat dissipation device, or be a closed metal heat dissipation device or a semi-open metal heat dissipation device. Further, the metal heat dissipation device 10 can be made of at least one of aluminum, aluminum alloy, copper, and copper alloy.

In step (b), a sputtered metal layer 20 that is patterned is formed on an upper surface 11 of the metal heat dissipation device 10 by sputtering. Further, at least one masking area 90 is formed on the upper surface 11 of the metal heat dissipation device 10 by a masking process, such as by arranging a masking jig on the surface of the metal heat dissipation device 10, by printing ink on the surface of the metal heat dissipation device 10, and by arranging an electroplating tape on the surface of the metal heat dissipation device 10, so that a metal layer is not formed in the at least one masking area 90, thereby forming the sputtered metal layer 20 that is patterned on the upper surface 11 of the metal heat dissipation device 10.

In one embodiment, the sputtered metal layer 20 can be formed by sputtering a single metal. The single metal can be nickel, copper, or silver. Therefore, the sputtered metal layer 20 can be a sputtered nickel layer, a sputtered copper layer, or a sputtered silver layer.

In one embodiment, the sputtered metal layer 20 can be formed by sputtering an alloy metal. The alloy metal can be nickel alloy, copper alloy, or silver alloy. Therefore, the sputtered metal layer 20 can also be a sputtered nickel alloy layer, a sputtered copper alloy layer, or a sputtered silver alloy layer.

It is worth mentioning that, a thickness of the metal sputtered layer 20 is preferably between 1 μm and 3 μm, and the sputtered metal layer 20 covers an area less than 90% of an area of the upper surface 11 of the metal heat dissipation device 10.

Furthermore, the sputtered metal layer 20 is formed at a vacuum level of less than 10⁻² mbar. In addition, the sputtered metal layer 20 is formed at a sputtering power of 1000 W or more, so that a film formed by sputtering has high purity, good compactness, and uniformity of molding.

Therefore, through forming the sputtered metal layer 20 that is patterned on the upper surface 11 of the metal heat dissipation device 10, a functional area that is patterned is formed on the upper surface 11 of the metal heat dissipation device 10, so as to effectively enhance a soldering ability, a corrosion resistant property, or a sintering ability of the metal heat dissipation device 10.

Furthermore, according to the above, the embodiments of the present disclosure also provide an automobile heat dissipation device having a patterned surface coating, and the automobile heat dissipation device includes a metal heat dissipation device 10 and a sputtered metal layer 20. Further, the sputtered metal layer 20 is partially formed on an upper surface 11 of the metal heat dissipation device 10 by sputtering, so that the sputtered metal layer 20 is patterned and a thickness of the sputtered metal layer 20 is between 1 μm and 3 μm. In addition, the sputtered metal layer covers an area less than 90% of an area of the upper surface 11 of the metal heat dissipation device 10.

In one embodiment, the metal heat dissipation device 10 can have a fin structure 101 disposed therein. The metal heat dissipation device 10 can be a water-cooled metal heat dissipation device or an air-cooled metal heat dissipation device. The metal heat dissipation device 10 can be a closed metal heat dissipation device or a semi-open metal heat dissipation device. In addition, the metal heat dissipation device 10 can be made of at least one of aluminum, aluminum alloy, copper, and copper alloy.

In one embodiment, the sputtered metal layer 20 can be made of nickel, nickel alloy, copper, copper alloy, silver, or silver alloy.

### Beneficial Effects of the Embodiments

In conclusion, in the method for manufacturing the patterned surface coating of the automobile heat dissipation device and the automobile heat dissipation device having the patterned surface coating provided by the present disclosure, by virtue of “providing the metal heat dissipation device” and “forming the sputtered metal layer that is patterned on the upper surface of the metal heat dissipation device by sputtering, allowing the thickness of the metal sputtered layer to be between 1 μm and 3 μm, and allowing the sputtered metal layer to cover the area less than 90% of the area of the upper surface of the metal heat dissipation device,” the functional area that is patterned is formed on the upper surface of the metal heat dissipation device, so as to effectively enhance the soldering ability, the corrosion resistant property, or the sintering ability of the metal heat dissipation device.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A method for manufacturing a patterned surface coating of an automobile heat dissipation device, comprising:
(a) providing a metal heat dissipation device; and
(b) forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device.

2. The method according to claim 1, wherein in step (b), at least one masking area is formed on a surface of the metal heat dissipation device by a masking process, so that the sputtered metal layer is not formed in the at least one masking area, and the sputtered metal layer that is patterned is formed on the surface of the metal heat dissipation device.

3. The method according to claim 1, wherein the sputtered metal layer is formed at a vacuum level of less than 10⁻² mbar.

4. The method according to claim 3, wherein the sputtered metal layer is formed at a sputtering power of 1000 W or more.

5. The method according to claim 1, wherein a fin structure is disposed in the metal heat dissipation device.

6. The method according to claim 5, wherein the metal heat dissipation device is a water-cooled metal heat dissipation device or an air-cooled metal heat dissipation device.

7. The method according to claim 5, wherein the metal heat dissipation device is a closed metal heat dissipation device or a semi-open metal heat dissipation device.

8. The method according to claim 5, wherein the metal heat dissipation device is made of at least one of aluminum, aluminum alloy, copper, and copper alloy.

9. The method according to claim 1, wherein the sputtered metal layer is made of nickel, nickel alloy, copper, copper alloy, silver, or silver alloy.

10. An automobile heat dissipation device having a patterned surface coating, comprising:
a metal heat dissipation device; and
a sputtered metal layer partially formed on an upper surface of the metal heat dissipation device by sputtering so that the sputtered metal layer is patterned, wherein a thickness of the sputtered metal layer is between 1 μm and 3 μm, and the sputtered metal layer covers an area less than 90% of an area of the upper surface of the metal heat dissipation device.
